(19) United States
(12) Patent Application Publication
(10) Pub. No.: US 2016/0181847 A1
(43) Pub. Date: Jun. 23, 2016

(54) Programmable Current Discharge System

(71) Applicant: Rocketship, Inc., Provo, UT (US)

(72) Inventor: Zack B. Bomsta, Provo, UT (US)

(21) Appl. No.: 14/922,833

(22) Filed: Oct. 26, 2015

Related U.S. Application Data
(60) Provisional application No. 62/068,563, filed on Oct. 24, 2014.

(51) Int. Cl. H02J 7/00; G01R 31/36

(52) U.S. Cl. CPC H02J 7/0072; G01R 31/3627

(57) ABSTRACT

A current discharge system is provided to supply a specified amount of high current to a device, such as a battery management system. The current may be used, for example, to simulate a short circuit to ensure that the batter management system properly isolates the batter from the circuit. The system can also be used to handle nearly any desired amount of current. The system enables the control of high current through a number of fixed resistors and programmable resisters to obtain a desired current.

### BACKGROUND OF THE INVENTION

1. The Field of the Invention

The present invention relates generally to a system for testing and/or controlling current discharge. In one application, the present invention relates to a system for testing a battery management system to ensure that the battery management system is functioning properly.

2. State of the Art

There are numerous situations in which it is important to test the flow of current in a system. For example, some battery management systems are used to ensure that a battery is not over charged or over discharged and to isolate the battery from the circuit in the event of a short circuit. Over charging or over discharging can cause over-heating, fires, reduced battery life damage to other electrical components, and damage to the battery.

While many batteries discharge relatively small amounts of current, there are other situations wherein large current spikes are needed. For example, when starting an automobile, a short current spike of about 600 amps may be needed to start the engine. In large trucks and other vehicles which use large gasoline or diesel engines, the amperage required to turn over the engine may be several times that of an automobile. Thus, for example, it is not uncommon for the tractor of a semi-trailer to draw 2400 to 2800 amps when starting. In order to test the battery management system, the test system will be required to handle more than 2800 amps to ensure that the battery management system properly limits the amperage pulled from the batter. Testing such high amperage, however, typically requires very large systems and can be quite expensive.

Thus, there is a need for a programmable current discharge system which can handle high current while remaining relatively compact and economical.

### SUMMARY OF THE INVENTION

According to one aspect of the present disclosure, a current discharge test system is provided. The current discharge system includes a plurality of resistors and a plurality of current control modules to test current discharge up to a desired threshold.

According to one aspect of the disclosure, first, fixed resistor, such as an ultra-high current compact resister (hereinafter “HCCR”) may be provided. The compact resistor may be configured to handle a very high current (e.g. 100 to 1000 amps) without damage to the resistor. The compact resistor may include a compact resistor core which allows a high resistance in a relatively small space. Additionally the compact resistor may include a cooling system for limiting heat build-up due to the large current flowing through the resistor and to maintain a desirable temperature range for optimal resister performance.

According to another aspect of the disclosure, an ultra-high power programmable current control module (hereinafter “CCM”) may be provided, which effectively forms a digital potentiometer/ resistor. The CCM may be provided which allows the current discharge test and regulation system to control the amount of current to be discharged. By providing multiple CCMs together, the system can be used to provide a desired current output. Such can be provided, for example, to test a battery management system to ensure that the battery management system is properly controlling current draw out of the battery. If the battery management system fails to properly control the current discharge, the battery management system will exceed its limits and be destroyed. Obviously, it is preferable that such happens during quality control rather than during use, where failure could result in a fire or other damage to the vehicle.

In accordance with one aspect of the invention, the CCM includes Hall effects sensor for detecting current flow through a conductor. The Hall effects sensor sends a signal to a micro-control unit which processes the signal and creates an output based on the sensed current. The output from the micro-control unit that then forwarded to an OP amplifier which controls a plurality of MOSFETs. By regulating the voltage, the current flow can be regulated. Thus, for example, a feedback loop can be established with one CCM having 10, 20 or more MOSFETs and the current passing through the CCM regulated to achieve desired amperage.

In accordance with another aspect of the disclosure, a plurality of HCCRs and a plurality of CCMs can be disposed in communication with a high current source, such as a battery. Each HCCR can be paired with a CCM on a leg to provide a desired amount of the total current needed. Because the HCCR will only allow a certain amount of current to pass through to the CCM, additional current is forced to pass through additional legs of the circuit, thereby reducing the risk of a CCM blowing due to too much current.

In accordance with another aspect of the disclosure, each of the legs of the circuit are disposed to minimize the distance between the input conductor and the MOSFETs so that the MOSFETs get to a common current load as quickly as possible.

According to one aspect of the present disclosure, the system includes a wireless master control system to prevent magnetic fields created within the CCMs from interfering with control.

According to another aspect of the present disclosure, a master control may be provided which allows selecting control of each HCCR and CCM to thereby achieve a desired current draw.

### BRIEF DESCRIPTION OF THE DRAWINGS

Various embodiments of the present disclosure are shown and described in reference to the numbered drawings wherein:

FIG. 1 shows a perspective view of an HCCR in accordance with the principles of the present disclosure.

FIG. 2 shows an exploded view of the HCCR of FIG. 1;

FIG. 3 shows a top view of the HCCR of FIG. 1;

FIG. 4 shows an end view of the HCCR of FIG. 1;

FIG. 5 shows a front perspective view of a CCM in accordance with the present disclosure;

FIG. 6 shows a rear perspective view of the CCM of FIG. 5;

FIG. 7 shows an exploded view of the CCM of FIG. 5;

FIG. 8 shows a top view of the CCM of FIG. 5;

FIG. 9 shows a bottom view of the CCM of FIG. 5;

FIG. 10 shows a schematic of the current discharge test and regulation system;

FIG. 11 shows a schematic view of the programmable feedback look of the CCM of FIG. 5;

FIG. 12 shows a top view of a bank of HCCRs 10 and CCMs;

FIGS. 13 through 15 show alternate configurations of buses and MOSFETs; and

FIGS. 16 and 17 are schematics of one CCM/variable resistor and a cooling system in accordance with one application of the present invention.

It will be appreciated that the drawings are illustrative and not limiting of the scope of the invention which is defined by the appended claims. The embodiments shown accomplish various aspects and objects of the invention. It is appreciated that it is not possible to clearly show each element and aspect of the invention in a single figure, and as such, multiple figures are presented to separately illustrate the various details of the invention in greater clarity. Similarly, not every embodiment need accomplish all advantages of the present invention.

### DETAILED DESCRIPTION

The invention and accompanying drawings will now be discussed in reference to the numerals provided therein so as to enable one skilled in the art to practice the present invention. The skilled artisan will understand, however, that the methods described below can be practiced without employing these specific details, or that they can be used for purposes other than those described herein. Indeed, they can be modified and can be used in conjunction with products and techniques known to those of skill in the art in light of the present disclosure. For example, while the description often discusses applications for arthroscopic surgery, the technique is not limited to that field and may apply to other types of surgery as well. The drawings and descriptions are intended to be exemplary of various aspects of the invention and are not intended to narrow the scope of the appended claims. Furthermore, it will be appreciated that the drawings may show aspects of the invention in isolation and the elements in one figure may be used in conjunction with elements shown in other figures.

Reference in the specification to “one embodiment,” “one configuration,” “an embodiment,” or “a configuration” means that a particular feature, structure, or characteristic described in connection with the embodiment may be included in at least one embodiment, etc. The appearances of the phrase “in one embodiment” in various places may not necessarily limit the inclusion of a particular element of the invention to a single embodiment, rather the element may be included in other or all embodiments discussed herein.

Furthermore, the described features, structures, or characteristics of embodiments of the present disclosure may be combined in any suitable manner in one or more embodiments. In the following description, numerous specific details are provided, such as examples of products or manufacturing techniques that may be used, to provide a thorough understanding of embodiments of the invention. One skilled in the relevant art will recognize, however, that embodiments discussed in the disclosure may be practiced without one or more of the specific details, or with other methods, components, materials, and so forth. In other instances, well-known structures, materials, or operations may not be shown or described in detail to avoid obscuring aspects of the invention.

Before the present invention is disclosed and described in detail, it should be understood that the present invention is not limited to any particular structures, process steps, or materials discussed or disclosed herein, but is extended to include equivalents thereof as would be recognized by those of ordinarily skill in the relevant art. More specifically, the invention is defined by the terms set forth in the claims. It should also be understood that terminology contained herein is used for the purpose of describing particular aspects of the invention only and is not intended to limit the invention to the aspects or embodiments shown unless expressly indicated as such. Likewise, the discussion of any particular aspect of the invention is not to be understood as a requirement that such aspect is required to be present apart from an express inclusion of the aspect in the claims.

It should also be noted that, as used in this specification and the appended claims, singular forms such as “a,” “an,” and “the” may include the plural unless the context clearly dictates otherwise. Thus, for example, reference to “a spring” may include an embodiment having one or more of such springs, and reference to “the layer” may include reference to one or more of such layers.

As used herein, the term “substantially” refers to the complete or nearly complete extent or degree of an action, characteristic, property, state, structure, item, or result to function as indicated. For example, an object that is “substantially” enclosed would mean that the object is either completely enclosed or nearly completely enclosed. The exact allowable degree of deviation from absolute completeness may in some cases depend on the specific context, such that enclosing the nearly all of the length of a lumen would be substantially enclosed, even if the distal end of the structure enclosing the lumen had a slit or channel formed along a portion thereof. The use of “substantially” is equally applicable when used in a negative connotation to refer to the complete or near complete lack of an action, characteristic, property, state, structure, item, or result. For example, structure which is “substantially free of” a bottom would either completely lack a bottom or so nearly completely lack a bottom that the effect would be effectively the same as if it completely lacked a bottom.

As used herein, the term “about” is used to provide flexibility to a numerical range endpoint by providing that a given value may be “a little above” or “a little below” the endpoint while still accomplishing the function associated with the range.

As used herein, a plurality of items, structural elements, compositional elements, and/or materials may be presented in a common list for convenience. However, these lists should be construed as though each member of the list is individually identified as a separate and unique member.

Concentrations, amounts, proportions and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually. This same principle applies to ranges reciting only one numerical value as a minimum or a maximum Furthermore, such an interpretation should apply regardless of the breadth of the range or the characteristics being described.

Distal and proximal, as used herein, are from the perspective of the person using the currently control system. Thus, proximal means nearer to the user and distal means farther from the person using the system.

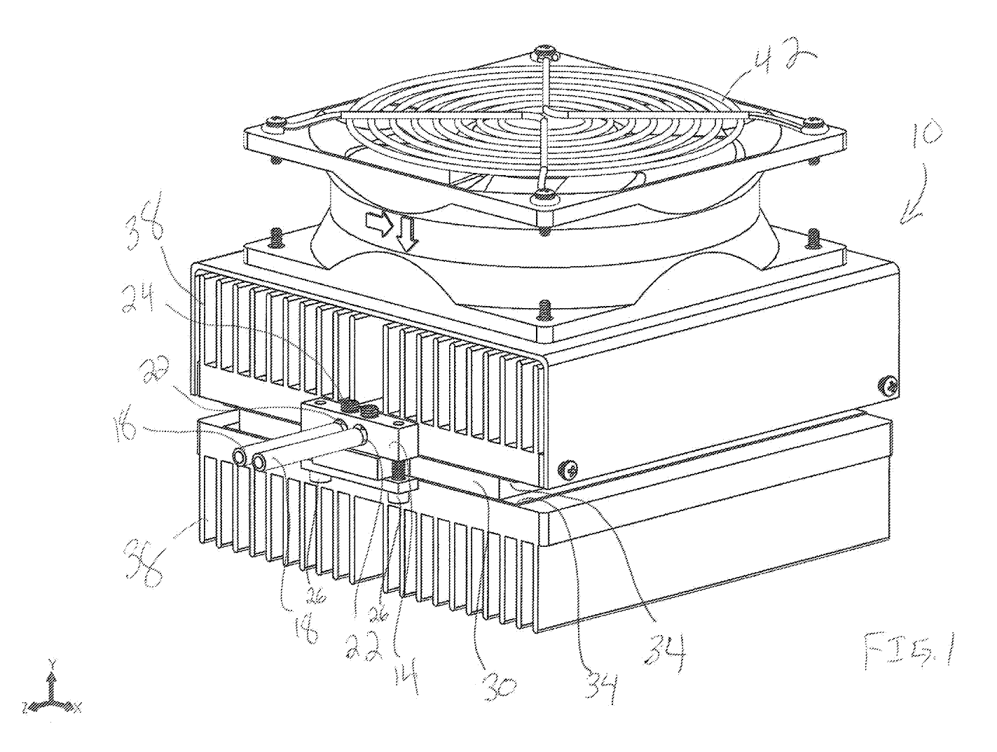

Turning now to FIG. 1, there is shown a perspective view of a first, fixed resistor, such as an HCCR, generally indicated at 10, which may be used to regulate very high amperage (i.e. 100+ amps). The HCCR 10 may include an attachment socket 14 for connecting the HCCR to power conductors 18 which carries current to the HCCR. As shown the attachment socket 14 includes two holes 22 for inserting the power conductors 18 and fasteners 24 for securing the power conductors in the attachment socket. Secondary fasteners 26 may be used to hold the attachment socket 14 to the remainder of the HCCR 10.

The attachment socket 14 is in electrical communication with a resistive element 30. It will be appreciated that the resistance of the resistive element is inversely proportional to the cross-sectional area of the resistive element. Additionally, the material from which the resistive element is made and the length of the resistive element also have a significant impact on resistivity.

Disposed on either side of the resistive element 30 is a non-conductive isolation layer 34. The non-conductive isolation layer 34 is designed to electrically isolate the resistive element 30 from a plurality of cooling elements 38, such as heat sinks, disposed on either side of the resistive element. Because the heat of the resistive element 30 will also affect resistivity, the non-conductive isolation layer prevents current from passing into the cooling elements and effectively by-passing the resistive element.

Also shown in FIG. 1 is a fan 42. The fan may be selectively driven to pull heat out of the cooling elements 38 to ensure that the HCCR 10 is operating within a desired temperature band to obtain the desired resistivity.

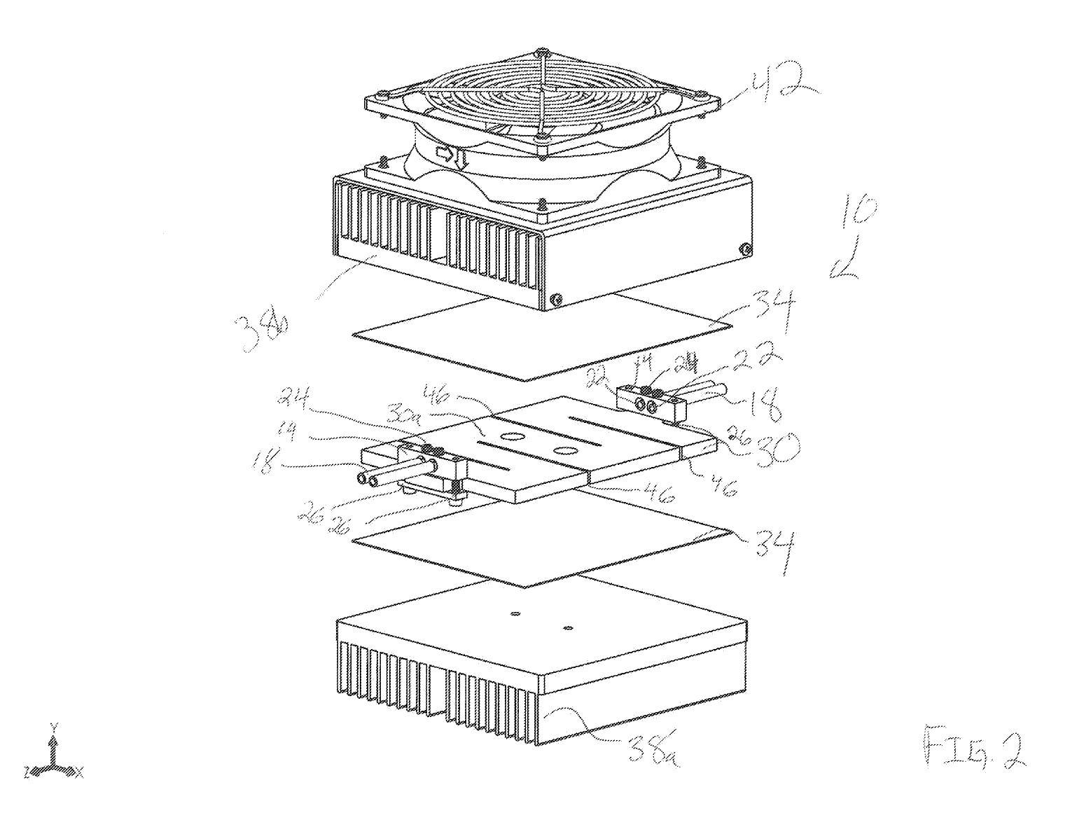

Turning now to FIG. 2, there is shown an exploded view of the HCCR 10 of FIG. 1. The lower cooling element 38a may be formed from various metals or other materials which are known in the art. The lower cooling element 38a is shown spaced apart from a lower non-conductive isolation layer 34, which may be formed from silicone or other suitable non-conductive material which will substantially prevent the current from traveling out the resistive element 30 and into the lower cooling element 38a.

In accordance with one aspect of the present disclosure, the resistive element 30 is made from a layer of graphite. The graphite may be anywhere from 1/16^{th} of an inch to greater than an inch in thickness. In one current embodiment, the layer of graphite is between about ¼ inch and ½ inch in thickness. Because the resistivity of the resistive element 30 is in part a function of a cross-sectional area of the resistor, the graphite may be formed or cut with a plurality of slots or notches 46. The notches 46 effectively change a sheet of graphite into a serpentine resistor wherein the cross-sectional area of the resistor is the distance between the notch and either an end or adjacent notch in the graphite times the thickness of the graphite. Thus, for one representative example used for testing a semi-truck battery management system, the resistive element 30 may have a length which is ¼^{th} to ½ inches in thickness and between 1 and 2 inches in width, thereby providing a cross-sectional area of between about ¼^{th} sq. in. to 1 sq. inch. As shown in FIG. 2, section 30a of the resistive element 30 may be wider than the other sections to accommodate for the two holes 52 shown therein.

The attachment sockets 14 are attached at opposing ends of the resistive element 30 by the secondary fasteners 26. Power conductors 18 may extend from both ends of the resistive element 30. Thus, to pass through the power conductors 18, the current must pass through the resistive element 18. As will be explained in additional detail below, the resistive element 30 limits the amount of the current which may be directed to a digitally programmable resistor in the form of the CCM.

Disposed above the resistive element 30 another electrically non-conductive isolation layer 34 may be used to electrically isolate the resistive element 30 from the upper cooling element 38b. The fan 42 is shown attached to the upper cooling element. It will be appreciated that a variety of cooling elements may be used and a fan is not required. For example, a hydraulic cooling system could be used.

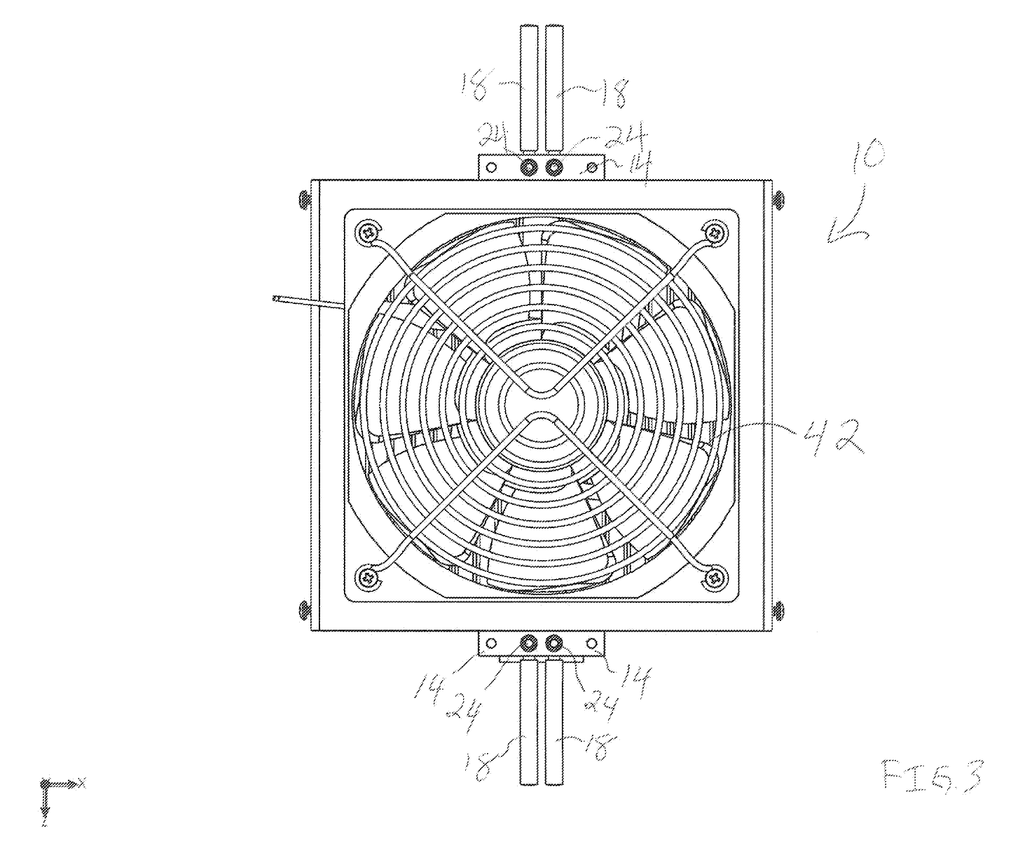

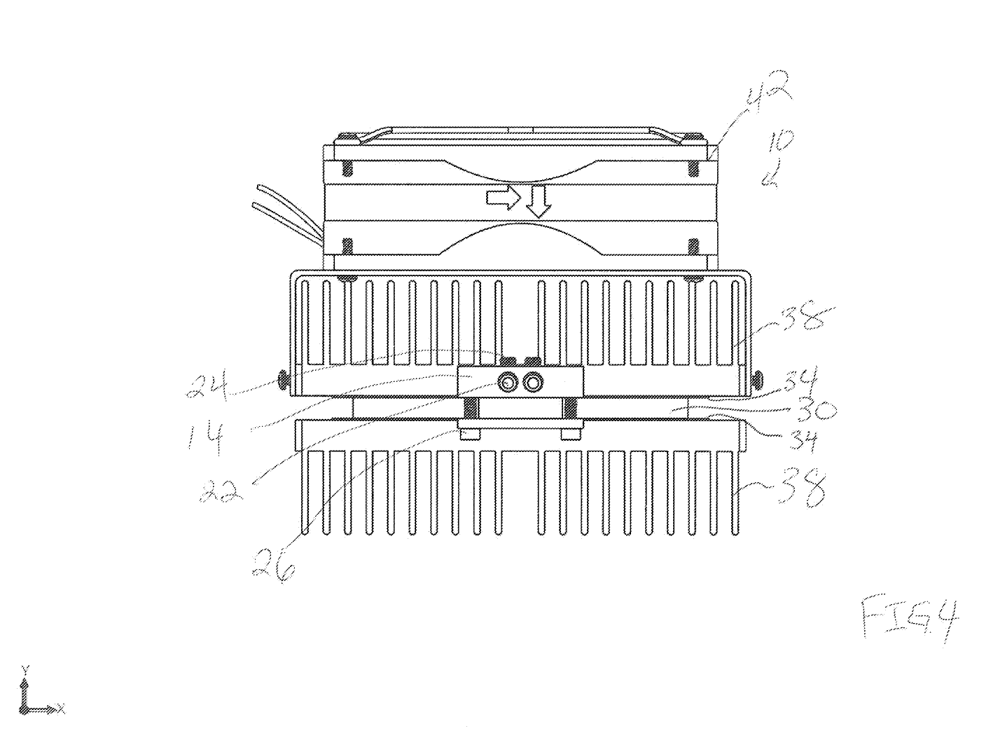

FIG. 3 shows a top view of the HCCR 10. The elements which are visible are given common numbering with that used in FIGS. 1 and 2. FIG. 4 shows an end view of the HCCR 10 including the cooling elements 38, the attachment socket 14, fasteners 22, secondary fasteners 26, the resistive element 30, the non-conductive isolation layers 34 and the fan 42.

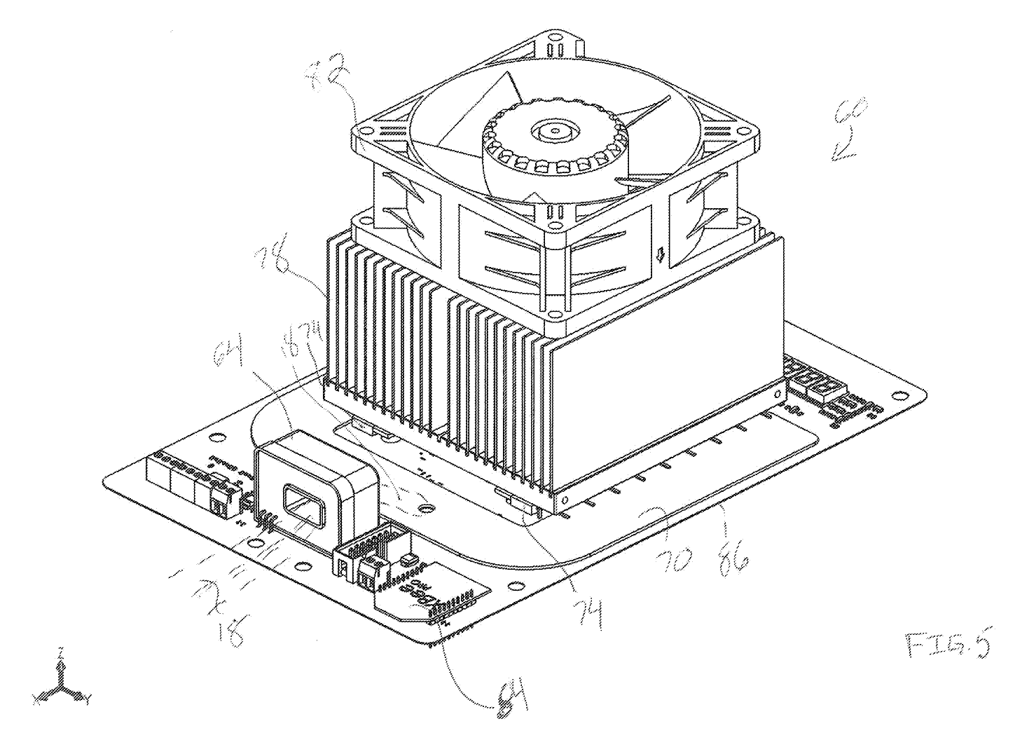

Turning now to FIG. 5, there is shown a perspective view of a digitally programmable resistor in the form of a current control module (CCM), generally indicated at 60. One problem with using a digitally programmable resistor in a high current situation is that the current can damage the circuitry. Use of the HCCR with the CCM can prevent such damage.

The CCM 60 may include a Hall effects sensor 64 which determines the current passing through the power conductors 18 (shown in dashed lines). The power conductors 18 are attached to a first bus bar 70. The first bus bar 70 may be made from copper or a variety of other materials. The first bus bar 70 may be columnated so that the current is directed along two or more columns. In conventional circuit boards, a plurality of MOSFETs is typically arranged in the linear array. Current passing down a power line will engage the MOSFETs in sequential order. While such a scenario works well in low current configurations, in high current situations is common to burn out the first MOSFET before the current can equalize across the array of MOSFETs.

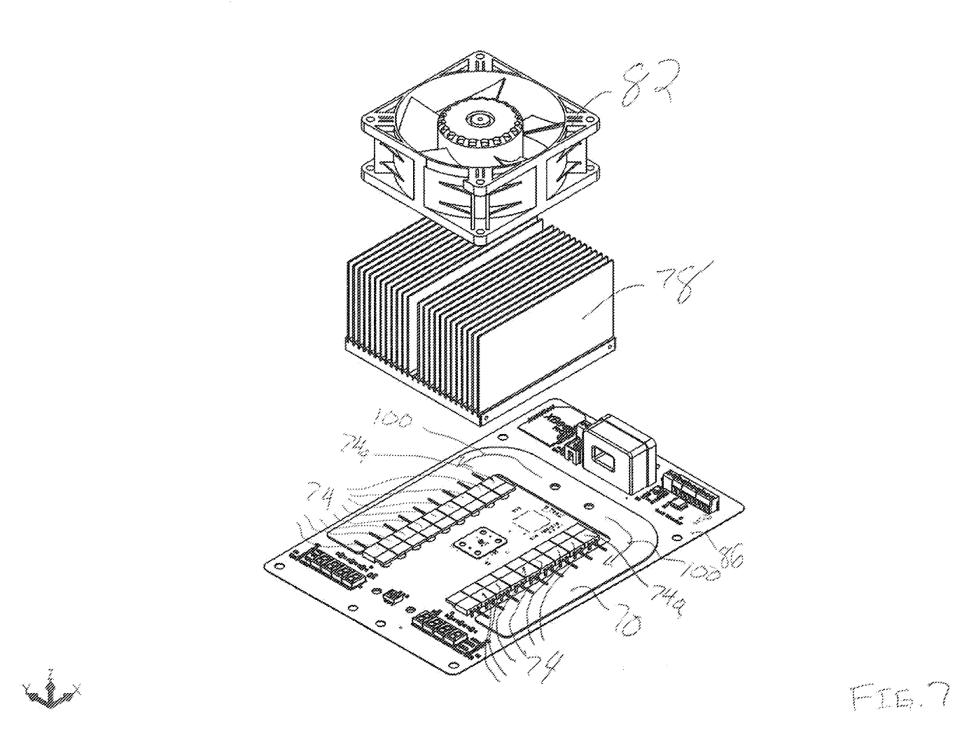

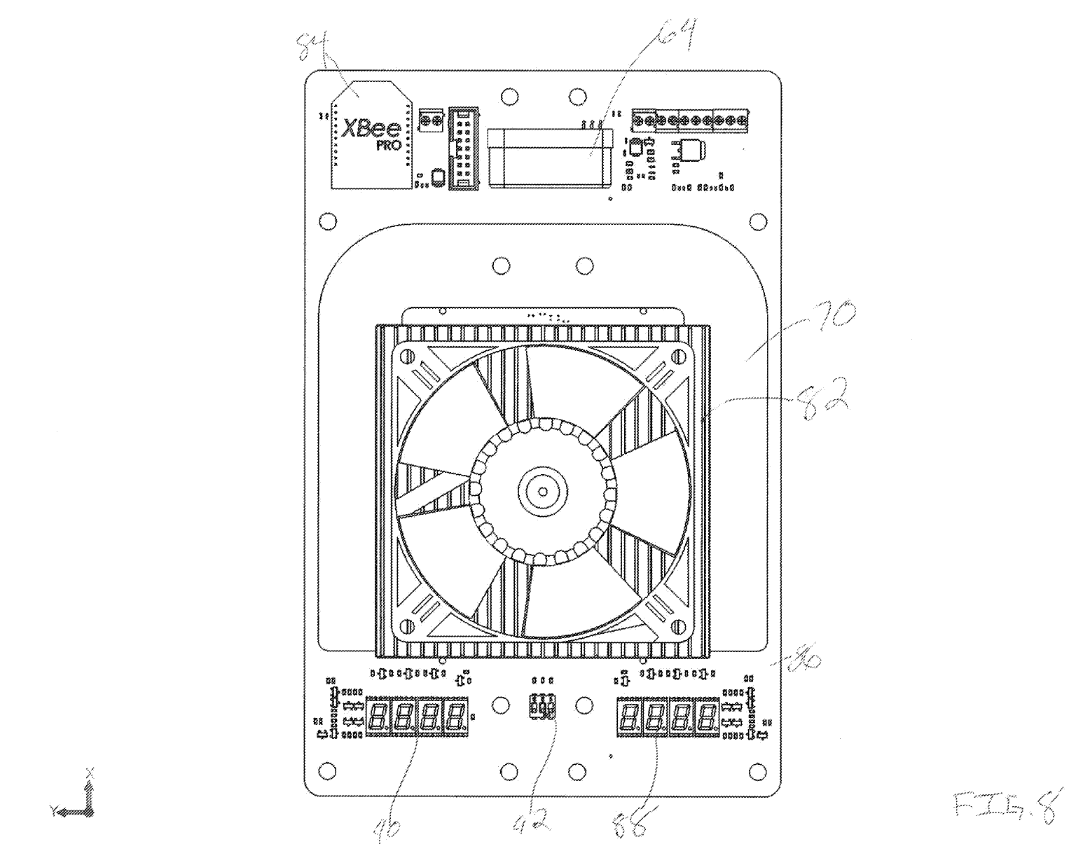

In accordance with one aspect of the present invention, the first bus bar 70 is attached to a plurality of semi-conductor switches, for example, MOSFETs 74 (most visible in FIG. 7). Other types of semi-conductor switches may also be used. Because the first bus bar 70 is columnated, the first two MOSFETs 74 receive the current at approximately the same time, thereby cutting the current load of any particular MOSFET in half. The current continues down the first bus bar 70 until all of the MOSFETs are receiving current.

Because the MOSFETs 74 receive a substantial amount of current, substantial heat is created. Additionally, temperature changes can affect MOSFET performance. Thus, a cooling (temperature regulation) element 78 may be disposed above the MOSFETs 74 to prevent the MOSFETs from other heating and to keep the MOSFETS in a desired temperature range. The cooling element 78 may be connected to a fan 82 or other cooling element.

Also shown in FIG. 5 is a wireless controller 84 which allows a wireless master control (not shown in FIG. 5) to selectively control the MOSFETs 74 to regulate the amount of current being allowed to pass. Also shown in FIG. 5 is a circuit board 86 or other substrate on which the MOSFETs 74 and the first bus bar are mounted.

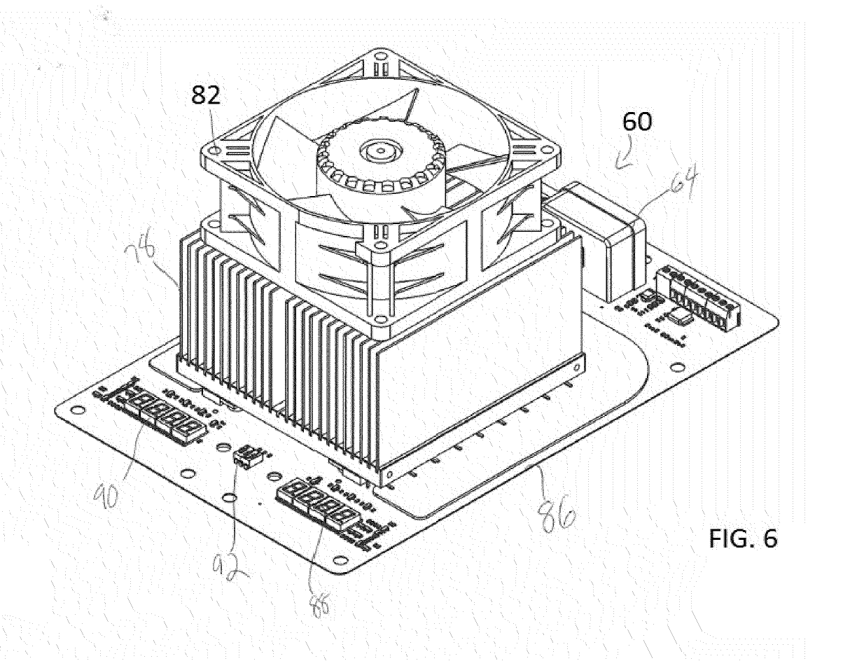

FIG. 6 shows a rear view of the CCM 60 and is number in accordance with the description above. FIG. 6 also shows displays 88 and 92 for displaying the temperature of the CCM 60 and the current being passed through the CCM. A plurality of switches 92 may be used identify an individual CCM from a group of CCMs.

FIG. 7 shows an exploded view of the CCM 60. The various parts are numbered in accordance with the discussion of FIGS. 5 and 6. As can be seen, a number of MOSFETs 74 are attached to the first bus bar 70. The first two MOSFETs 74a are spaced equidistant from the attachment points where the power conductors 18 are attached to the first bus bar 70 as represented by arrows 100. The next two MOSFETs 74 then receive the current and so on. By columnating the array of the MOSFETs 74 (i.e. putting them in columns), each of the MOSFETs receives power more closely in time than a conventional linear array. It will be appreciated in accordance with the present disclosure that the columnated design could use three, four or more columns so that three, four, etc., MOSFETs receive current at substantially the same time, thereby reducing the risk of a MOSFET being overloaded.

Turning now to FIG. 9, there is shown a bottom view of the CCM 60 shown in FIG. 5. The MOSFETs 74 may be disposed on the circuit board 86 and have leads 74c, etc., which are connected to a second bus board 104. The second bus board 104 may also be columnated, although doing so is not necessary. The current passing from the MOSFETs 74 is collected and so that the current coming out of the MOSFETs 74 is collected and passed to the load.

Also shown on the bottom is a pair of switches 110, 112 which may be MOSFETs, which are used to control whether the MOSFETs are active or shut down. Also shown is a micro-controller 114 which is used to regulate the MOSFETs to control the amount of current passing into the second bus bar 104.

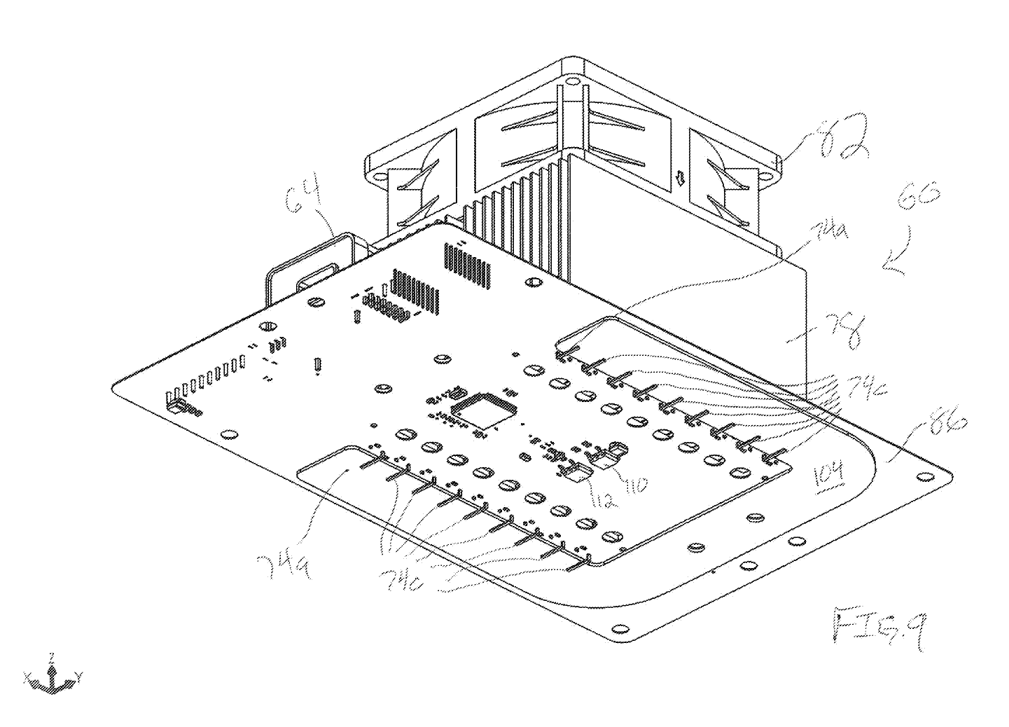

Turning now to FIG. 10, there is shown a schematic of the feedback loop which is used in the CCM 60. Current passes through the Hall effects sensor 64 via the power conductor(s) 18. The Hall effects sensor 64 may send a signal to a micro-controller unit 114 which processes the signals and generates an output signal. Communication line 116 to the micro-controller unit 114 may include an analog-to-digital converted and the communication line from the micro-controller unit may include a digital to analog converted. The signal from the micro-controller unit 114 regulates an OPAMP 116. The OPAMP 116 adjusts the voltage in the MOSFETs 74 and thereby controls the current passing out of the MOSFETs 74.

Also shown in FIG. 10 are switches 110 and 112, which may be MOSFETs, for selectively turning off or turning on the MOSFETs 74. A wireless master control 120 is provided because the fields within the feedback loop can interfere with control.

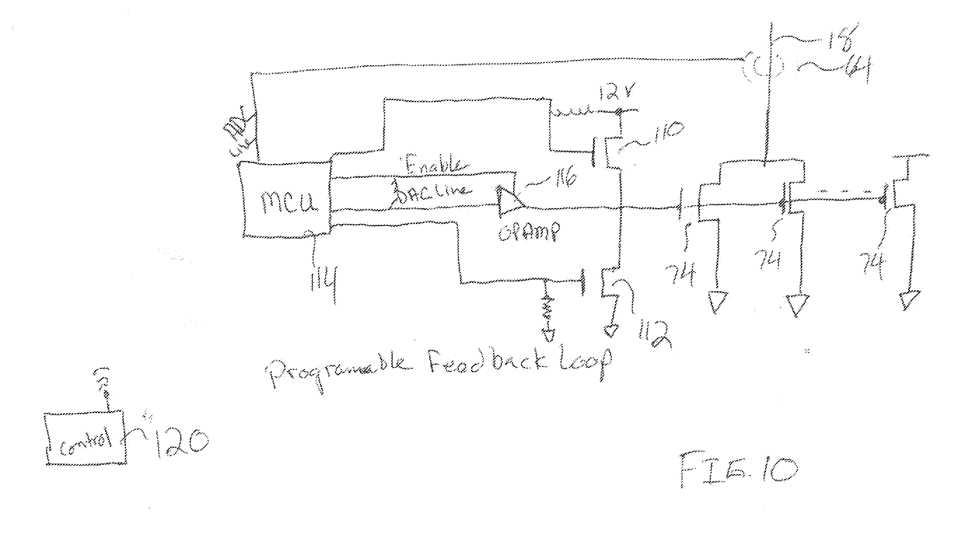

Turning now to FIG. 11, there is shown a schematic of the system, generally indicated at 130. Current passes into the power conductor 18 and is passed down a number of legs 18a, 18b, 18n, etc. Each of the legs 18 includes a first, fixed resistor, such as HCCR 10. The first, fixed resistor 10 is provided to provide a first, generally fixed resistance range (resistance will vary somewhat based on temperature, etc.) so that a current within a desired range passes to the digital potentiometer/resister formed by the CCM 60. Thus the first leg may produce a given amount of current, which may be constantly changing within a general range. Likewise, the second leg and each other leg may produce a given amount of current, which may be constantly changing. The master feedback control 120 controls each leg 18a, 18b, 18n by regulating the CCM 60 disposed along that leg in light of temperature and other current affecting factors so that the sum of the currents (I1-In) produce a desired current. Thus, the system may be programmed to obtain a desired current within a substantial range and the system can be adjusted to handle nearly any range desired by adding additional legs.

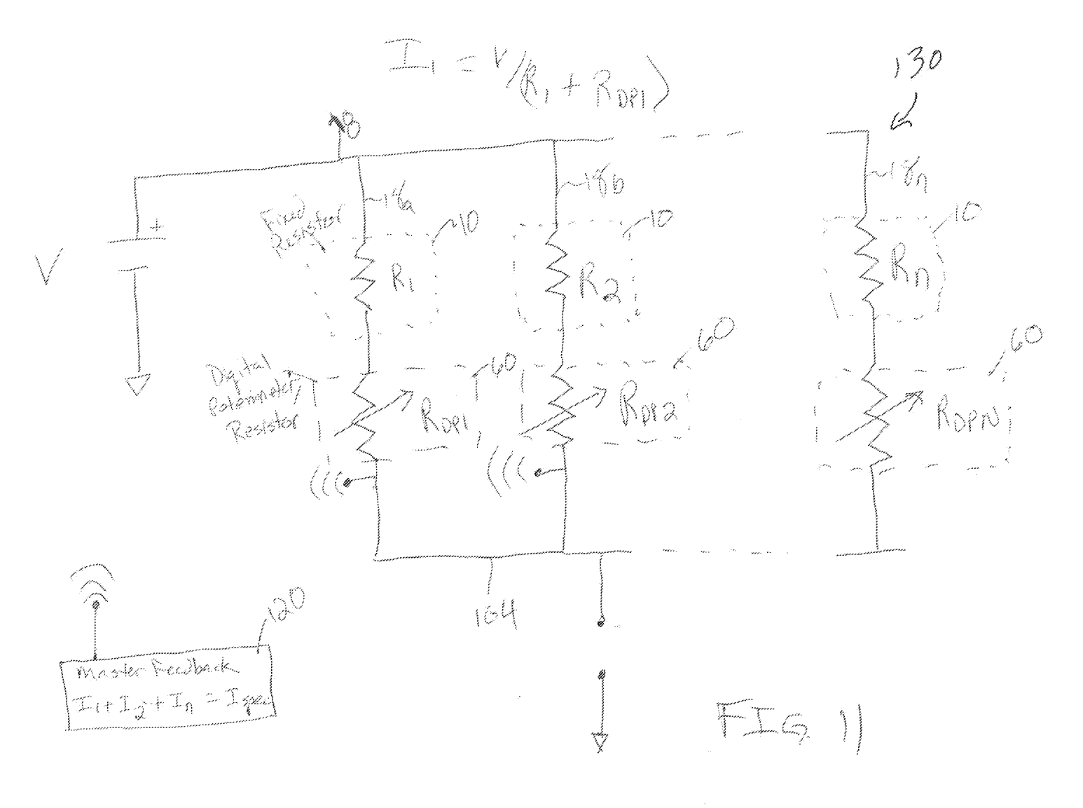

FIG. 12 shows a top view of a bank of HCCRs 10 and CCMs 60 consistent with the description above. As many legs 18a, 18b, 18n may be used as necessary to handle the amount of current desired in the system. Thus, for example, ten HCCRs and CCMs could be used to handle a current of 5000 amps.

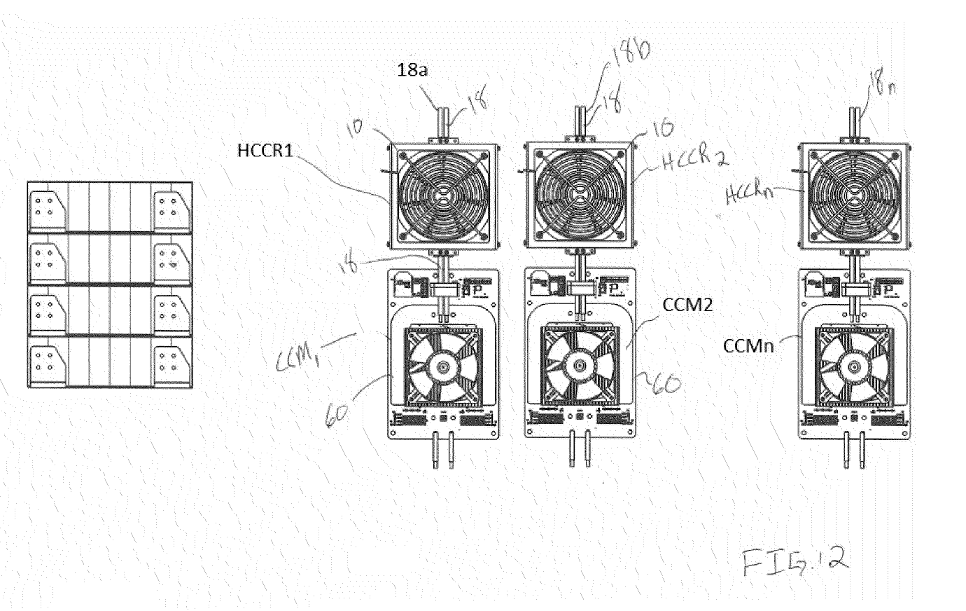

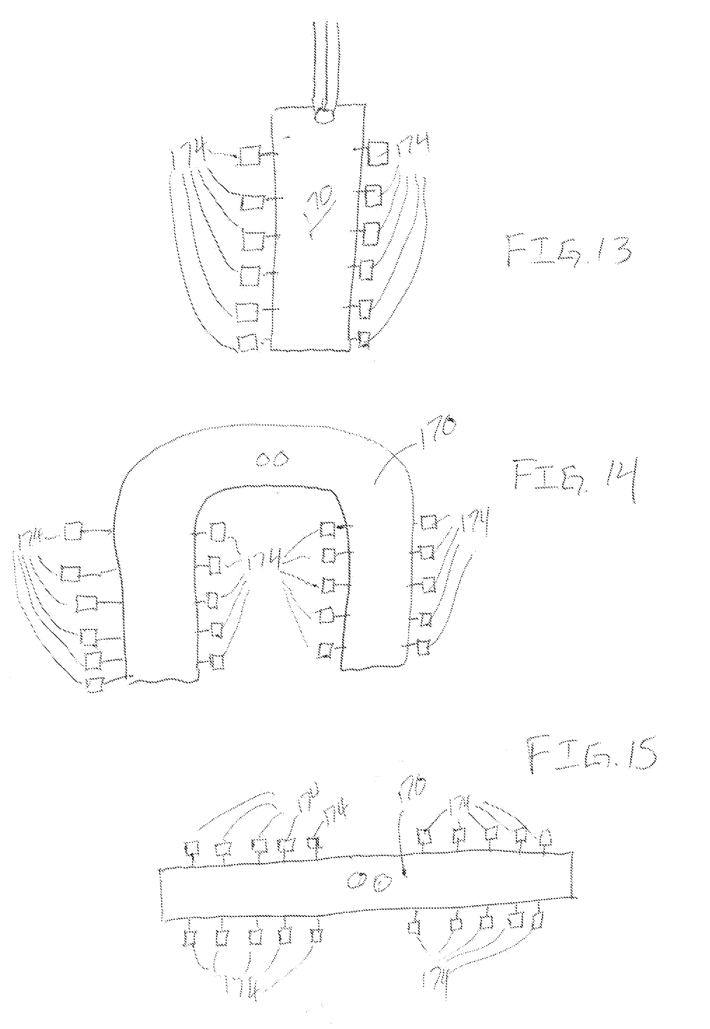

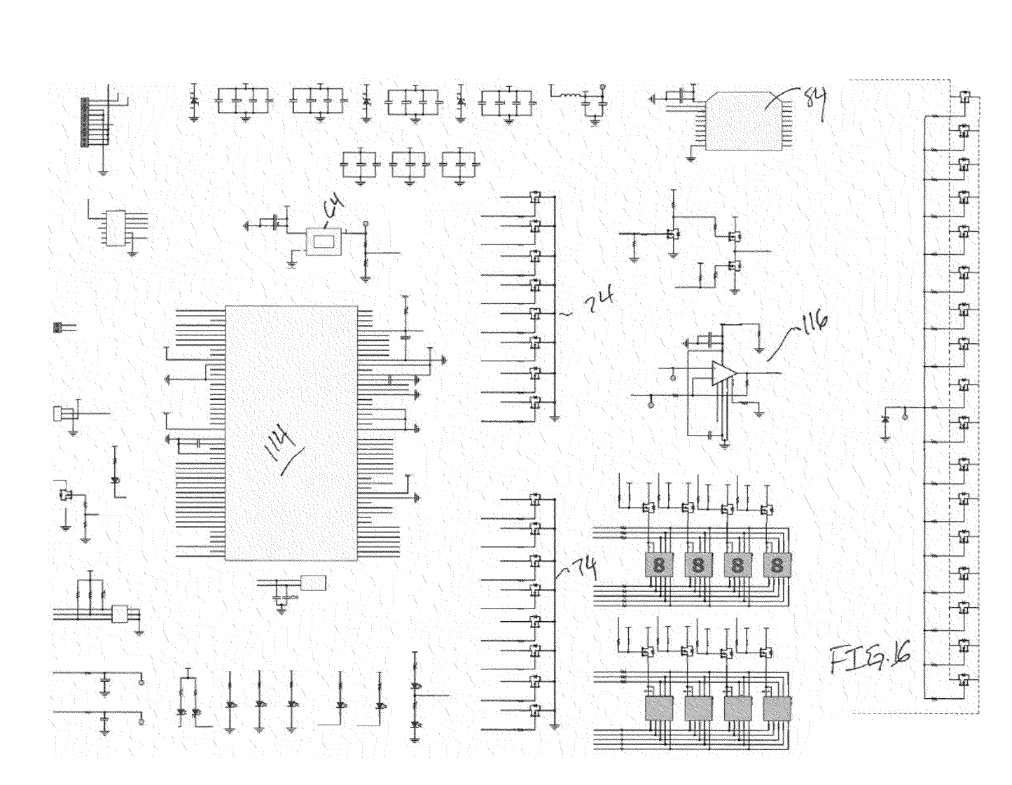

Turning now to FIGS. 13 through 15 there are shown three alternate configurations of a bus bar 170 and MOSFETs 174. By columnating the MOSFETs 174 the risk that the first MOSFETs will fail under the high current is reduced.

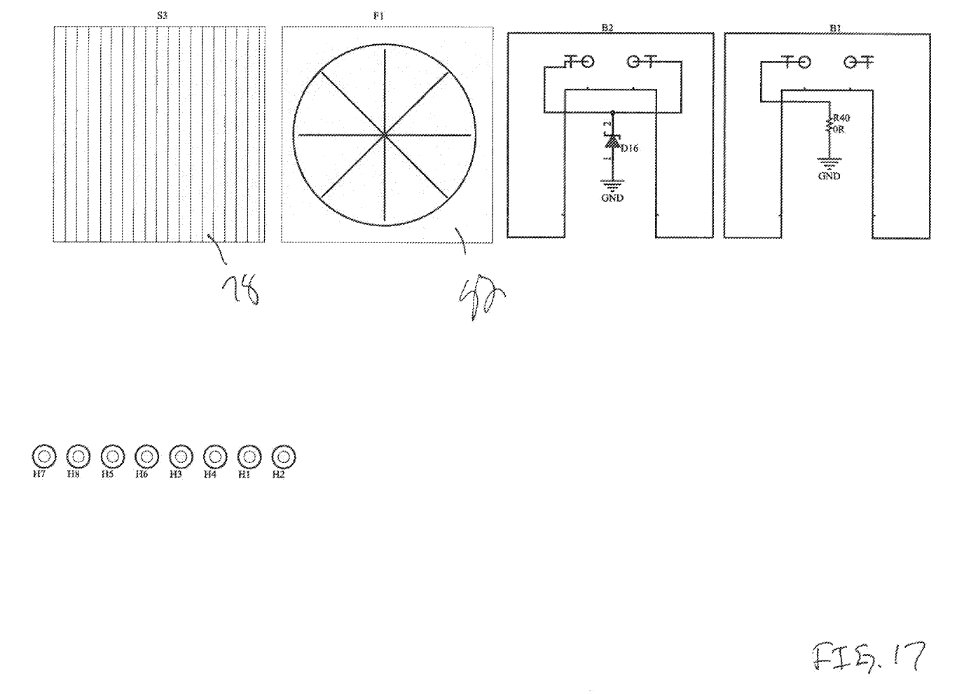

FIG. 16 shows a detailed schematic of a CCM/variable resistor. Claim 17 shows a schematic of a cooling system.

There is thus disclosed an improved current discharge test system and method of use. It will be appreciated that numerous changes may be made to the present invention without departing from the scope of the claims.

What is claimed is:

1. A programmable current discharge system comprising:
a power conductor for carrying a current;
first, fixed resistor;
a second, variable resistor which is programmable to pass current in a desired range; and
a master controller for controlling the amount of current passed by the second, variable resistor.

2. The programmable current discharge system of claim 1, wherein the first, fixed resistor comprises a graphite resistive element.

3. The programmable current discharge system of claim 1, wherein the first, fixed resistor has a resistive element having a serpentine shape.

4. The programmable current discharge system of claim 2, wherein the graphite resistive element is between 1/16 and 1 inch in thickness.

5. The programmable current discharge system of claim 3, wherein the graphite resistive element is between ¼ and ½ inch in thickness.

6. The programmable current discharge system of claim 1, having a resistive element, a cooling element disposed above the resistive element and a cooling element disposed below the resistive element.

7. The programmable current discharge system of claim 6, further comprising an electrically non-conductive isolating layer disposed between the resistive element and the cooling elements.

8. The programmable current discharge system of claim 1, wherein the second, variable resistor comprises a plurality of columnated semi-conductor switches.

9. The programmable current discharge system of claim 1, wherein the second, variable resistor includes a sensor for determining current in the power conductor, a plurality of semi-conductor switches and a micro-control unit for receiving signals from the sensor and for generating signals to change current passing through the semi-conductor switches.

10. The programmable current discharge system of claim 9, wherein the plurality of semi-conductor switches comprise MOSFETs.

11. The programmable current discharge system of claim 9, wherein the micro-control unit is disposed in communication with an OPAMP for regulating voltage to the plurality of MOSFETs to regulate current passing through the MOSFETs.

12. A method for discharging a desired current, the method comprising:
passing an electrical current along a power conductor;
passing the electrical current through a first, fixed resistor and a second, variable resistor and selectively controlling the second, variable resistor to obtain a desired current output range.

13. The method of claim 12, wherein the variable resistor comprises a plurality of columnated semi-conductor switches and wherein the method comprises passing the current through the plurality of columnated semi-conductor switches.

14. The method of claim 12, wherein the method comprises applying voltage to the columnated semi-conductor switches to alter the amount of current passing through the columnated semi-conductor switches.
